(19) United States
(12) Patent Application Publication
(10) Pub. No.: US 2003/0060003 A1
(43) Pub. Date: Mar. 27, 2003

(54) Capacitor device for a semiconductor circuit configuration, and fabrication method

(76) Inventors: Thomas Hecht, Dresden (DE); Harald Seidl, Feldkirchen (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/233,693

(22) Filed: Sep. 3, 2002

(30) Foreign Application Priority Data
Aug. 31, 2001 (EP) EP 01 121 010.1

(51) Int. Cl. H01L 21/8242; H01L 21/20

(52) U.S. Cl. 438/240; 438/253; 438/396

(57) ABSTRACT

In order, with an increased integration density, to be able to provide capacitors for semiconductor circuit configurations with the same or an increased capacitance, first and/or second electrode regions are formed from a metallic material, a metal nitride or the like. In addition or as an alternative, a dielectric region which lies between the electrode regions may be formed using a material with an increased dielectric constant.

### BACKGROUND OF THE INVENTION

1. Field of the Invention

The invention lies in the semiconductor technology field. More specifically, the invention relates to a capacitor device for a semiconductor circuit configuration, and to a method for the fabrication of such a capacitor device.

A primary aspect in the ongoing development of modern semiconductor circuit configurations and in particular semiconductor memory technologies is that of increasing the integration density. In this context, it is attempted to increase the number of switching elements or memory cells which can be formed per unit area in a semiconductor substrate or the like. The object is to achieve circuits, in particular semiconductor memories, which are as small, compact, and powerful as possible.

Many semiconductor circuit configurations require capacitor configurations, for example including storage capacitors or the like. These capacitor configurations are then formed as trench capacitors or trench-structure capacitors or they are in the form of stacked capacitors. In dynamic read/write memories, e.g. of the DRAM type (dynamic random access memory), capacitor configurations of this type are used, for example, in one-transistor cells as memory element, a select transistor connecting the storage capacitor to a bit line.

In very general terms, the structural design and the fabrication of capacitor structures or capacitor configurations are problematical and of interest if the integration density is to be increased. In the above text and the text which follows, a capacitor structure or a capacitor configuration is to be understood in very general terms as meaning an arrangement comprising a first material region, which serves as an electrode region, substantially directly spatially adjacent to a second material region, serving as a dielectric region.

The invention therefore deals in very general terms with the development of the structure of these material configurations of electrode and dielectric. A counterelectrode or a second electrode region is under certain circumstances not specifically to be provided, but rather may if appropriate also result implicitly or inherently as the “bulk” or “ground.”

In prior art capacitor devices or the like, in particular for a semiconductor memory device, a DRAM memory or the like, a trench structure which includes at least one recess or a trench is formed, for example, in a semiconductor substrate, a passivation region and/or a surface region thereof. Furthermore, a configuration having a first electrode or a first electrode region, a second electrode or a second electrode region, and a dielectric region provided substantially between them, in particular in this order, in each case in substantially continuous form, is formed at least in the region of the trench, at least wall regions or edge regions and/or base regions of the respective trench being substantially covered and/or lined. The arrangement of the electrode regions with the dielectric provided between them then forms in each case exactly the corresponding capacitor device.

On account of the requirements with regard to the increased integration of known semiconductor memory devices, it is consequently also necessary for the corresponding capacitor devices to be miniaturized further. However, for reliable operation of capacitor devices of this type, it is essential to provide a certain minimum capacitance. However, since the capacitance of the capacitor—in particular with otherwise constant parameters—is strongly correlated to the surface-area dimensioning of the capacitor device, accordingly, to achieve a minimum capacitance, a minimum size, i.e. a minimum extent of the opposite electrode regions with the dielectric region between them, is required. However, maintaining a minimum size runs contrary to the wish to further increase the integration density in semiconductor memory devices.

### SUMMARY OF THE INVENTION

It is accordingly an object of the invention to provide a capacitor device for a semiconductor device and a fabrication method which overcome the above-mentioned disadvantages of the heretofore-known devices and methods of this general type and which leads to a trench-structure capacitor device with which suitable minimum capacitances can easily be ensured even when the dimensions are reduced further.

With the foregoing and other objects in view there is provided, in accordance with the invention, a capacitor device for a semiconductor circuit configuration, comprising:

an electrode region formed in a structure selected from a semiconductor substrate, a passivation region, an insulation region, and a surface region thereof, and a dielectric region formed spatially adjacent, and contiguously with, the electrode region;

the electrode region containing a material selected from the group consisting of metallic materials and metal nitrides; and

the dielectric region being an electrochemical oxidation region of a part of the electrode region.

In other words, the objects relating to the device are achieved in that, according to the invention, a first electrode region is formed in a semiconductor substrate, a passivation region, insulation region and/or surface region thereof, and a dielectric region is formed substantially directly spatially adjacent to the first electrode region, in particular in this order and/or in particular in each case in substantially continuous form.

Furthermore, in the first solution to the object which relates to the device, it is provided, according to the invention, for at least the first electrode region to be formed at least in part from a metallic material, a metal nitride and/or the like or to include such a material.

In addition or as an alternative—according to the second solution relating to the device—to the latter aspect or combination of features, according to the invention there is provision for the dielectric region to be formed at least in part from a material with an increased dielectric constant in particular compared to SiO₂, Si₃N₄ and/or the like and to include such a material.

These two measures may be provided as alternative proposed solutions, but may also implement the inventive concept together.

Therefore, the invention provides and/or implements two measures in combination or as alternatives in order to increase the capacitance of the corresponding capacitor device. One measure is wherein by the formation of at least the first electrode region as a metallic material, a metal nitride and/or the like. The other measure provides for the formation of the dielectric region from a material with an increased dielectric constant.

In this context, the basic idea in both cases is to increase the specific capacitance of the capacitor device produced compared to conventional capacitor devices. This means that, according to the invention, an increased capacitance can be provided per unit area of the corresponding electrode region.

According to the first inventive solution to the object, this is achieved by the fact that the electrode materials used are metallic materials, in particular metals, metal nitrides and/or the like. Specifically optionally doped semiconductor materials are conventionally used to form the electrode regions.

These conventional semiconductor materials, for example polysilicon or the like, on account of their particular electronic structure, have a charge density which is only slightly distributed over surface regions and is much more distributed over spatial regions, through which a space charge region is formed. By contrast, no space charge region is formed at metallic regions, but rather substantially an areal charge distribution is formed at the surface or interface of the electrode. Accordingly, when metallic electrodes are used, low effective layer thicknesses result for the dielectric, which, in the capacitor devices according to the invention, leads to a higher capacitance for corresponding electrode surface areas. This means that, when metal electrodes are used, the effective thickness of the dielectric is reduced by the extent of the space charge region which is then eliminated.

By contrast, in the other inventive solution, there is provision for the dielectric to be formed with a comparatively increased dielectric constant. It is customary to use materials such as silicon dioxide SiO₂, silicon nitride Si₃N₄ and/or the like. However, the capacitance of a capacitor device has a linear correlation with respect to the dielectric constant of the dielectric provided between the electrode regions. Accordingly, when selecting the corresponding dielectric material, the specific capacitor capacitance can likewise be decisively influenced, i.e. can also be increased.

According to another embodiment, there is provision for at least a second electrode region to be formed in particular substantially directly spatially adjacent to the dielectric region, which second electrode region in particular consists at least in part of at least one metallic material, a metal nitride and/or the like or includes such a material.

In a particularly preferred embodiment of the capacitor device according to the invention, there is provision for the first electrode region, the dielectric region and/or the Second electrode region to be formed in each case in layer form, in particular in multilayer form. A layered structure fox one or more of these regions may be advantageous, for example, with a view to compatibility with the surrounding materials or for further increasing the specific capacitance of the capacitor device which is to be formed.

Above all, it is particularly advantageous if, according to a further embodiment of the capacitor device according to the invention, the first electrode region, the dielectric region and/or the second electrode region are formed substantially conformally. Forming the respective layers or regions conformally results in optimum utilization of the structure formed on the semiconductor substrate, the passivation region and/or the surface region in the available area. To keep the formation of leakage currents at a low level, the dielectric is or has been advantageously formed as a substantially conformal region.

It is particularly advantageous if, according to a particularly preferred embodiment of the capacitor device-according to the invention, the respective dielectric region is formed as a physical and/or chemical conversion region of at least a part of the first electrode region, in particular as a preferably electrochemical oxidation region and/or the like and/or in particular in a conformal manner.

In this embodiment, it is in fact the combination of the two inventive solutions which comes to bear, namely the simultaneous provision of a metallic material for the first electrode region and of a material of increased dielectric constant for the dielectric region. In this context, it is recommended, for example, to provide the dielectric region, for example, as an oxidation layer of the metal layer or metal nitride layer of the first electrode region which has been formed, by means of a suitable process. Therefore, this procedure implements both solution concepts in accordance with the invention, and at the same time advantageously results in a particularly stable structure, since the first electrode region and the dielectric region are, as it were, joined integrally to one another.

Even in the case of a first electrode region which—before conversion—is not formed conformally, the conversion advantageously results in the formation of a substantially conformal dielectric region.

It is particularly advantageous if the first electrode region and/or the second electrode region are formed at least in part from Al, W, WN, Ta, TaN, Ti, TiN, Hf, Hfn, Zr, ZrN, Mo, MoN, Y, YN, La, LaN, Ce, CeN and/or the like and/or a combination or compound thereof.

Furthermore, in addition or as an alternative it is advantageous if the dielectric region is formed at least in part from Al₂O₃, TiO₂, Ta₂O₅, HfO₂, ZrO₂, WO₃, MoO₂, Y₂O₃, La₂O₃, CeO₂, MgO and/or the like and/or a combination or compound thereof.

The capacitor device is advantageously formed as a trench-structure capacitor device or as a trench capacitor.

In this context, there is provision in particular for a trench structure, which includes at least one recess or a trench, to be formed in a semiconductor substrate, a passivation region, insulation region and/or a surface region thereof, for the first electrode region, if appropriate the second electrode region and the dielectric region provided substantially between them, in particular in this order and/or in particular in each case in substantially continuous form, to be formed in particular in the corresponding trench, and as a result for at least wall regions or edge regions and/or base regions of the respective trench to be substantially covered and/or lined, at least in part with the first electrode region, if appropriate with the second electrode region and/or with the dielectric region.

With the above and other objects in view there is also provided, in accordance with the invention, a method of fabricating a capacitor device for a semiconductor circuit configuration, which comprises:

providing a structure selected from the group consisting of a semiconductor substrate, a passivation region, an insulation region, and a surface region thereof;

forming in the structure a configuration with a first electrode region and a dielectric region spatially adjacent thereto, in the recited order and in contiguous form; and thereby

forming the first electrode region with a material selected from the group consisting of metallic materials and metal nitrides; and

subsequently forming the dielectric region by electrochemical oxidation in a conformal manner.

In other words, the solutions to the objects relating to the method provide a method for fabricating a capacitor device for a semiconductor circuit configuration and in particular for a semiconductor memory device, a DRAM or the like, wherein an arrangement having a first electrode region and a dielectric region provided substantially directly spatially adjacent thereto, in particular in this order and/or in particular in each case in substantially continuous form, is formed in a semiconductor substrate, a passivation region, insulation region and/or a surface region thereof.

In the method according to the invention for fabricating a capacitor device for a semiconductor circuit configuration and in particular for a semiconductor memory device, a DRAM or the like, furthermore, according to a first solution, there is provision for at least the first electrode region to be formed at least in part from at least one metallic material, a Metal nitride and/or the like.

Alternatively—according to a second solution—or in addition, there is provision for the dielectric region to be formed at least in part from a material with an increased dielectric constant, in particular compared to SiO₂, Si₃N₄ and/or the like.

In further analogy to the solution to the object on which the invention is based relating to the device, in the fabrication method there is also provision for the first and/or second electrode regions to be formed at least in part from a metallic material, a metal nitride and/or the like or, as an alternative or in addition to this, for the dielectric material to be formed with a correspondingly increased dielectric constant.

Each of the two measures on their own and in particular their interaction makes it possible to provide capacitor devices which have a specific capacitance which is increased compared to conventionally fabricated capacitor devices, which still provide a sufficient capacitor capacitance to be able to ensure sufficient functionality even after further miniaturization and increasing of the integration density.

In this case too, both measures may be employed separately, or in combination with regard to the method.

According to another embodiment, there is provision for at least one second electrode region to be formed in particular substantially directly spatially adjacent to the dielectric region, which second electrode region in particular, consists at least in part of at least one metallic material, a metal nitride and/or the like or includes such a material.

In a particularly advantageous embodiment of the method according to the invention, there is provision for the first electrode region, the dielectric region and/or the second electrode region in each case to be formed in layer form, in particular in each case in multilayer form.

In a further advantageous embodiment of the fabrication method according to the invention, there is provision for the first electrode region, the dielectric region and/or the second electrode region to be formed in each case substantially isotropically, two-dimensionally, conformally, over a large surface area and/or over the entire surface area. The result of this is that, should certain annealing steps or further processing steps be required for the individual layers, the basic structure of the semiconductor substrate, of the passivation region or the like remains substantially protected. After the corresponding layer structures have been formed and. processed further, suitable patterning, for example by selective etching processors or the like, can then take place.

The first electrode region, the dielectric region and/or the second electrode region are advantageously each formed by deposition, in particular by a CVD process, by an ALD process, by an electrochemical conversion and/or deposition process and/or the like.

It is particularly advantageous that, according to a further embodiment of the method according to the invention for fabricating a trench-structure capacitor device, first of all the first electrode region is formed. Then, according to this embodiment, the dielectric region is formed by physically and/or chemically converting at least part of the first electrode region. This is achieved in particular by preferably electrochemical oxidation or the like and/or in particular in a conformal manner. The result of this measure is that both solution concepts of the invention are incorporated in an integrated process sequence. First of all, the first electrode material which is to be formed in metallic form is deposited and is then treated electrochemically, for example, resulting precisely in a dielectric region with an increased dielectric constant compared to conventional materials.

In a particularly advantageous embodiment of the fabrication method according to the invention, there is provision for the first electrode region and/or the second electrode region to be formed at least in part from Al, W, WN, Ta, TaN, Ti, TiN, Hf, HfN, Zr, ZrN, Mo, MoN, Y, YN, La, LaN, Ce, CeN and/or the like and/or a combination or compound thereof.

There is also provision for the dielectric region to be formed at least in part from A1203, TiO2, Ta205, HfO2, ZrO2, W03, M002, Y203, La203, CeC2, MgO and/or the like and/or a combination or compound thereof.

The capacitor device is advantageously formed as a trench-structure capacitor device or as a trench capacitor.

In particular, in this context there is provision for a trench structure, which includes at least one recess or a trench, to be formed in a semiconductor substrate, a passivation region, insulation region and/or a surface region thereof, for the first electrode region, if appropriate the second electrode region and the dielectric region provided substantially between them, in Particular in this order and/or in particular in each case in substantially continuous form, to be formed in particular in the corresponding trench, and for at least wall regions or edge regions and/or base regions of the respective trench to be substantially covered and/or lined, at least with part of the first electrode region, if appropriate of the second electrode region and/or of the dielectric.

These and further aspects of the present invention are explained in more detail with reference to the observations which follow:

Nowadays, so-called 1-transistor cells are used in dynamic random access memories, known as DRAMs. These cells comprise a storage capacitor and a select transistor which connects the storage electrode to the bit line. The storage capacitor is often formed as what is known as a trench capacitor, i.e. a hole is etched into the substrate and a dielectric and a storage electrode are introduced, doped polysilicon being used in the prior art. Currently, the doped silicon substrate, known as the buried plate, is used as counterelectrode.

The invention described here relates in particular to this type of memory, wherein trench storage capacitors or so-called trench-structure capacitor devices are used.

To further increase the storage density for future technology, generations, the feature size is being reduced from generation to generation. The increasingly small capacitor surface areas and the resulting decrease in the capacitance of the capacitor lead to problems with regard to operational reliability. Therefore, an important aim is to keep the capacitance of the capacitor at least constant despite the decreasing feature size. This can be achieved, inter alia, by increasing the surface charge density of the storage capacitor, A further possibility for increasing the capacitance of the capacitor consists in substituting the silicon layers which adjoin the dielectric with metallic layers which do not have a space charge region which is typical of silicon.

Previous attempted solutions with regard to the problems referred to above are based on increasing the available capacitor surface area for a predetermined feature size. This can be achieved, for example, by widening the trench, for example using the wet-bottle principle below the collar region or oxide collar, or by deposition of polysilicon with a rough surface, for example using the HSG process, in the trench.

On the other band, hitherto the surface charge density has conventionally been increased by reducing the thickness of the dielectric. Hitherto, exclusively various combinations of silicon dioxide SiO₂ and silicon nitride Si₃N₄ in combination with doped silicon electrodes have been used as dielectric material for trench capacitors or trench-structure capacitor devices. A further reduction in the thickness of these dielectrics is not possible, on account of the resulting high leakage currents.

The present invention makes it possible to increase the surface charge density by using new dielectrics in the trench capacitor, with an increased dielectric constant compared to dielectrics which have been used hitherto, without the leakage current being significantly increased. The procedures which have been proposed within the context of this invention are distinguished in particular by the fact that, first of all, a metallic film or a combination of metallic films or also metal nitrides is deposited in order to form a first or lower electrode region. These deposited layers are then oxidized by means of an electrochemical process. The deposition of the metallic films can be carried out by CVD, i.e. by chemical vapor deposition, by ALD, i.e. by atomic layer deposition, by electrochemical deposition and/or the like.

Suitable materials for the electrode layers are Al, W, WN, Ta, TaN, Ti, TiN, Hf, HfN, Zr, ZrN, Mo, MoN, Y, YN, La, LaN, Ce, CeN or similar materials.

Suitable materials for the dielectric layer are Al₂O₃, TiO₂, Ta₂O₅, HfO₂, ZrO₂, WO₃, MoO₂, Y₂O₃, La₂O₃, CeO₂, MgO or similar materials, in particular formed by electrochemical oxidation of the corresponding metal or metal nitride of the first electrode region.

Therefore, the basic ideas of the present invention are firstly to use new dielectrics with relatively high dielectric constants and to use metallic electrode layers in order to avoid space charge regions.

If the process flow allows the use of identical metals for the electrode and for the dielectric—in this case as the oxide of the metal—an advantage which should be noted is that the deposition does not have to take Place completely conformally, provided that the electrochemical oxidation takes place conformally. Nonconformal deposition results in a nonconformal metal electrode, which is to be considered considerably less critical than a nonconformally deposited dielectric.

As an exemplary embodiment, it is conceivable to form a metallic electrode layer and a dielectric with deposition of a metallic layer. Irrespective of this, it is also possible to deposit two or more metallic layers, either in order to generate mixed dielectrics or to use various metals for the electrodes. After a first metallic layer has been deposited in a trench structure for the trench capacitor, partial electrochemical oxidation of this metal layer is carried out.

The structure which is formed in this way can then be filled with another metal or with polysilicon as counter electrode.

Other features which are considered as characteristic for the invention are set forth in the appended claims.

Although the invention is illustrated and described herein as embodied in a capacitor device for a semiconductor circuit configuration, and method for its fabrication, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIGS. 1-5 are sequential sectional and diagrammatic views, each illustrating an intermediate stage in the fabrication method according to the invention, for producing a novel capacitor device in the form of trench capacitor.

### DESCRIPTION OF THE PREFERRED EMBODIMENTS

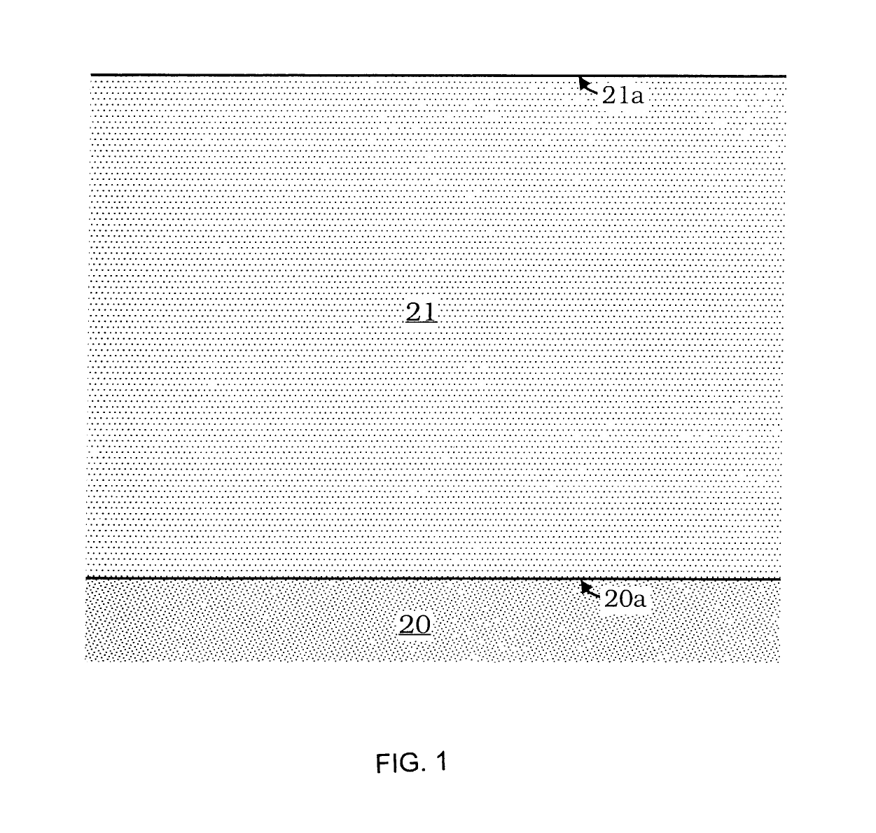

Referring now to the figures of the drawing in detail and first, particularly, to FIG. 1 thereof, the starting point for the formation of a trench-structure capacitor device according to the invention is the basic structure shown in FIG. 1, wherein a second substrate region 21 with a planar surface region 21a, in particular a second semiconductor substrate 21, is provided on a first substrate region 20, e.g. a first actual semiconductor substrate 20. The latter likewise has a substantially planar surface region 20a. The first semiconductor substrate 20 may have a corresponding basic CMOS structure. The substrate regions 20 and 21 may also form a single, continuous substrate region.

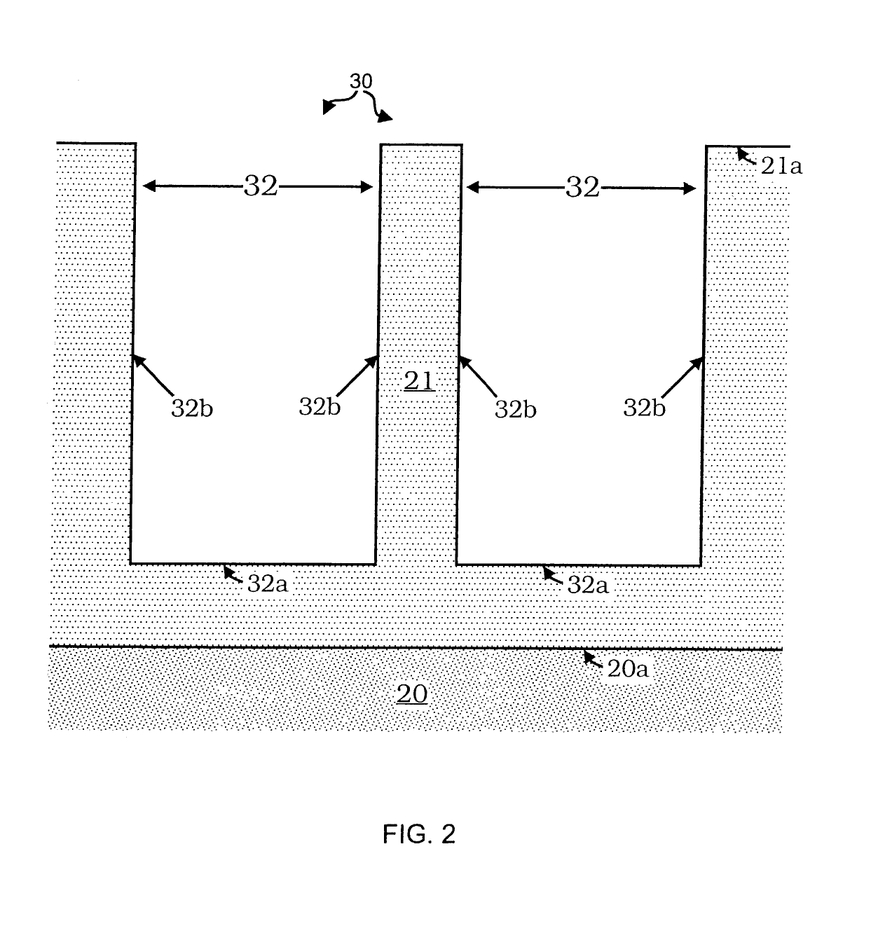

In the transition to the intermediate state shown in FIG. 2, a trench structure 30 is formed in the semiconductor substrate 21 or into the surface region 21a thereof by way of a suitable etching or lithography step. The trench structure, in the exemplary embodiment shown in FIG. 2, has two trenches 32 or recesses 32 with wall regions 32b and one base region 32a each.

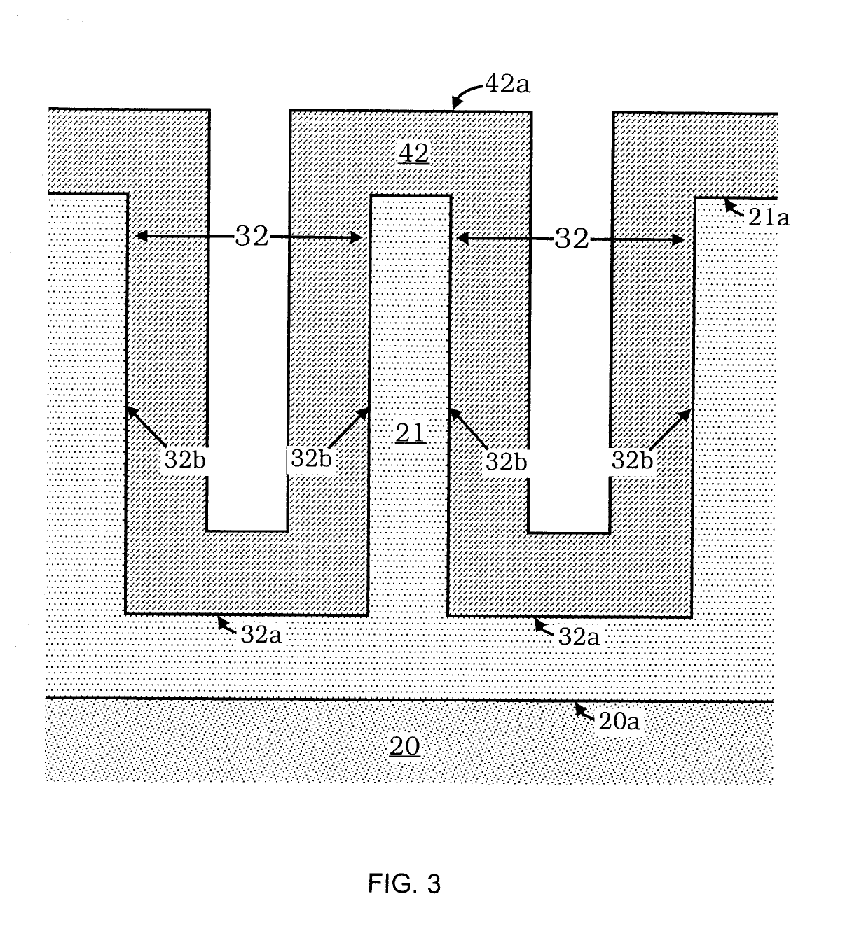

Then, as a transition to the intermediate state shown in FIG. 3, a material region 42 comprising a substantially metallic material is formed. The material region 42 is designed as a common material region for the first electrode region 44 which is to be formed and the dielectric region 46 which is to be formed and in this case consists of a metal, a metal nitride or the like.

As shown in FIG. 3, the deposition takes place in two-dimensional, complete-area or large-area and conformal manner. As a result, the trenches 32 of the trench structure 30 and in particular of the wall regions 32b and base regions 32a are covered or lined, preferably in a continuous and conformal manner.

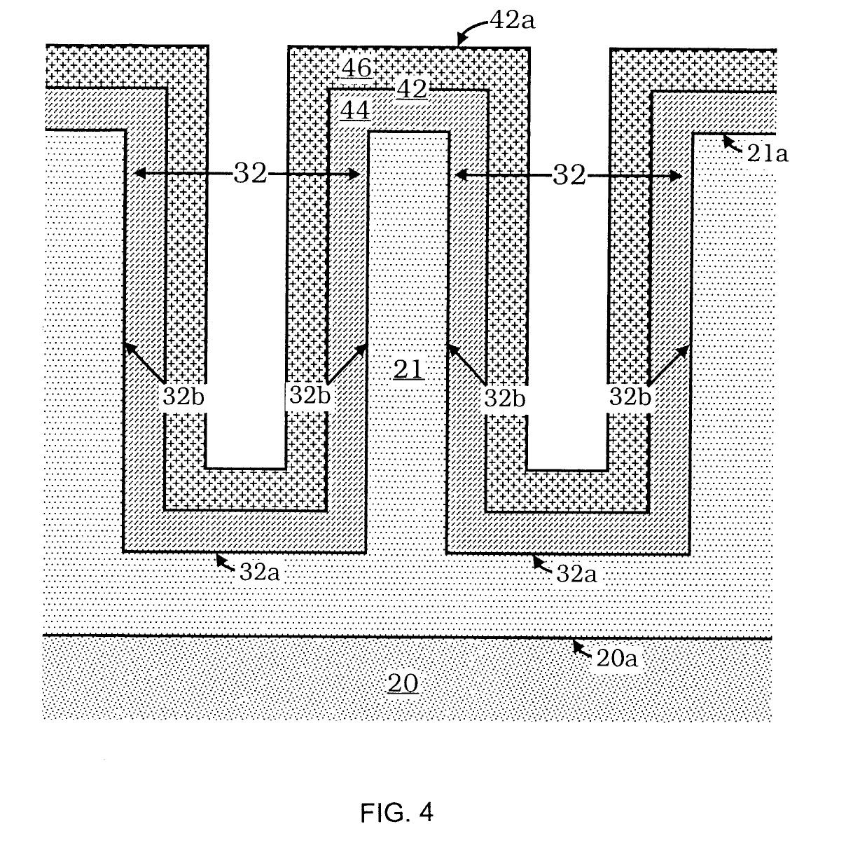

Next, as the transition to the intermediate state shown in FIG. 4, an electrochemical process is applied to the structure shown in FIG. 3, so that the surface region 42a of the material layer 42 is electrochemically converted. As a result of this procedure, the material layer 42 is converted into the first electrode region 44 and the dielectric region 46. The first electrode region 44 and the dielectric region 46 which follows it are therefore joined integrally to one another.

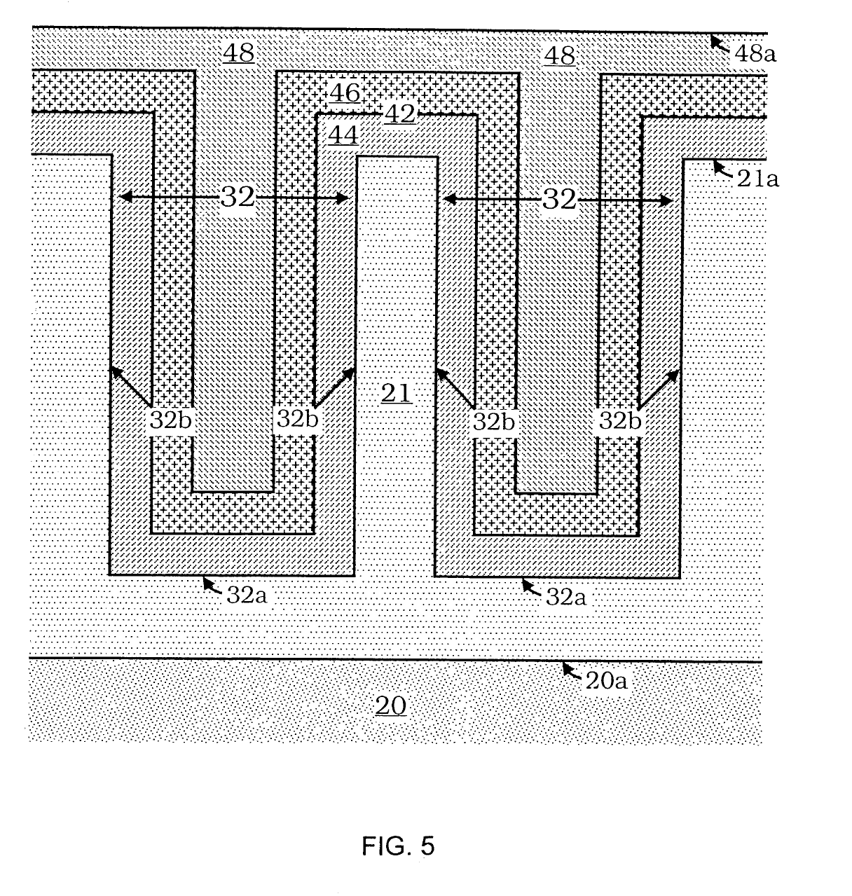

As the transition to the intermediate state shown in FIG. 5, the trench-structure capacitor device 40 is then completed in an inventive manner as a result of the second electrode region 48 being deposited in a two-dimensional manner in the form of a metallic layer. This is done in such a manner that on the one hand a surface region 48a is formed and on the other hand the recessed regions of the trenches 32 of the trench structure 30, which has, hitherto remained clear, are at least partially filled. As a result, the dielectric region 46 is completely covered by the second electrode region 48 at those locations.

We claim:

1. A capacitor device for a semiconductor circuit configuration, comprising:
an electrode region formed in a structure selected from the group consisting of a semiconductor substrate, a passivation region, an insulation region, and a surface region thereof, and a dielectric region formed spatially adjacent, and contiguously with, said electrode region;
said electrode region containing a material selected from the group consisting of metallic materials and metal nitrides; and
said dielectric region being an electrochemical oxidation region of a part of said electrode region.

2. The capacitor device according to claim 1, wherein said electrode region is at least in part formed from the material selected from the group consisting of metallic materials and metal nitrides.

3. The capacitor device according to claim 1, wherein said dielectric region is formed at least in part from a material with an increased dielectric constant relative to SiO₂ and Si₃N₄.

4. The capacitor device according to claim 1, wherein said dielectric region contains a material with an increased dielectric constant relative to SiO₂ and Si₃N₄.

5. The capacitor device according to claim 1, wherein said electrode region is a first electrode region, and a second electrode region adjoins said dielectric region, said second electrode region contains a material selected from the group consisting of metallic materials and metal nitrides.

6. The capacitor device according to claim 5, wherein said second electrode region consists at least in part of the material selected from the group consisting of metallic materials and a metal nitride.

7. The capacitor device according to claim 1, wherein at least one of said first electrode region, said dielectric region, and said second electrode region are each disposed in layer form.

8. The capacitor device according to claim 1, wherein at least one of said first electrode region, said dielectric region, and said second electrode region are each formed as a multilayer.

9. The capacitor device according to claim 1, wherein at least one of said first electrode region, said dielectric region, and said second electrode region are each formed conformally.

10. The capacitor device according to claim 1, wherein at least one of said first electrode region and said second electrode region are at least partially formed of a material selected from the group consisting of Al, AlN, W, WN, Ta, TaN, Ti, TiN, Hf, Hfn, Zr, ZrN, Mo, MoN, Y, YN, La, LaN, Ce, CeN, a combination thereof, and a compound thereof.

11. The capacitor device according to claim 1, wherein said dielectric region is at least partially formed of a material selected from the group consisting of Al₂O₃, TiO₂, Ta₂O₅, HfO₂, ZrO₂, WO₃, MoO₂, Y₂O₃, La₂O₃, CeO₂, MgO, a combination thereof, and a compound thereof.

12. The capacitor device according to claim 1 formed as a trench capacitor device.

13. The capacitor device according to claim 12, which comprises:
a trench structure having a trench, including walls, edges, and a base, formed in the structure selected from the group consisting of a semiconductor substrate, a passivation region, an insulation region, and a surface region thereof; and
wherein said electrode region and said dielectric region are formed in contiguous form in said trench; and
wherein said at least one of said wall regions, said edge regions, and said base regions of said respective trench are covered or lined at least with a part of said first electrode region and said dielectric region.

14. The capacitor device according to claim 13, wherein said electrode region is a first electrode region, and a second electrode region is contiguously formed on said dielectric region opposite said first electrode region.

15. A capacitor device for a semiconductor circuit configuration, comprising:
an electrode region formed in at least one structure selected from the group consisting of a semiconductor substrate, a passivation region, an insulation region, and a surface region thereof, and a dielectric region formed substantially directly spatially adjacent said electrode region;
said dielectric region being formed at least in part from a material with an increased dielectric constant relative to SiO₂ and Si₃N₄; and
said dielectric region being formed as an electrochemical oxidation region of a part of said first electrode region.

16. The capacitor device according to claim 15, wherein said electrode region and said dielectric region are integrated in and form an integral part of a semiconductor memory device.

17. The capacitor device according to claim 15, wherein said dielectric region and said electrode region form a substantially contiguous unit.

18. The capacitor device according to claim 15, wherein said electrode region contains a material selected from the group consisting of metallic materials and metal nitrides.

19. The capacitor device according to claim 18, wherein said electrode region is at least in part formed from the material selected from the group consisting of metallic materials and metal nitrides.

20. The capacitor device according to claim 10, wherein said electrode region is a first electrode region, and a second electrode region adjoins said dielectric region, said second electrode region contains a material selected from the group consisting of metallic materials and metal nitrides.

21. The capacitor device according to claim 20, wherein said second electrode region consists at least in part of the material selected from the group consisting of metallic materials and a metal nitride.

22. The capacitor device according to claim 10, wherein at least one of said first electrode region, said dielectric region, and said second electrode region are each disposed in layer form.

23. The capacitor device according to claim 10, wherein at least one of said first electrode region, said dielectric region, and said second electrode region are each formed as a multilayer.

24. The capacitor device according to claim 10, wherein at least one of said first electrode region, said dielectric region, and said second electrode region are each formed conformally.

25. The capacitor device according to claim 10, wherein at least one of said first electrode region and said second electrode region are at least partially formed of a material selected from the group consisting of Al, AlN, W, WN, Ta, TaN, Ti, TiN, Hf, Hfn, Zr, ZrN, Mo, MoN, Y, YN, La, LaN, Ce, CeN, a combination thereof, and a compound thereof.

26. The capacitor device according to claim 10, wherein said dielectric region is at least partially formed of a material selected from the group consisting of Al₂O₃, TiO₂, Ta₂O₅, HfO₂, ZrO₂, WO₃, MoO₂, Y₂O₃, La₂O₃, CeO₂, MgO, a combination thereof, and a compound thereof.

27. The capacitor device according to claim 10 formed as a trench capacitor device.

28. The capacitor device according to claim 27, which comprises:
a trench structure having a trench, including walls, edges, and a base, formed in the structure selected from the group consisting of a semiconductor substrate, a passivation region, an insulation region, and a surface region thereof; and
wherein said electrode region and said dielectric region are formed in contiguous form in said trench; and
wherein said at least one of said wall regions, said edge regions, and said base regions of said respective trench are covered or lined at least with a part of said first electrode region and said dielectric region.

29. The capacitor device according to claim 28, wherein said electrode region is a first electrode region, and a second electrode region is contiguously formed on said dielectric region opposite said first electrode region.

30. A method of fabricating a capacitor device for a semiconductor circuit configuration, which comprises:
providing a structure selected from the group consisting of a semiconductor substrate, a passivation region, an insulation region, and a surface region thereof;
forming in the structure a configuration with a first electrode region and a dielectric region spatially adjacent thereto, in the recited order and in contiguous form; and thereby
forming the first electrode region with a material selected from the group consisting of metallic materials and metal nitrides; and
subsequently forming the dielectric region by electrochemical oxidation in a conformal manner.

31. The method according to claim 30, which comprises forming the dielectric region at least in part from a material with an increased dielectric constant relative to SiO₂ and Si₃N₄.

32. The method according to claim 30, wherein the electrode region is a first electrode region and the method further comprises forming at least one second electrode region spatially adjacent the dielectric region, such that the second electrode region consists at least in part of at least one metallic material or a metal nitride or includes such a material.

33. The method according to claim 32, which comprises forming at least one of the first electrode region, the dielectric region, and the second electrode region in layer form.

34. The method according to claim 32, which comprises forming at least one of the first electrode region, the dielectric region, and the second electrode region in multilayer form.

35. The method according to claim 32, which comprises forming at least one of the first electrode region, the dielectric region, and the second electrode region in each case by selecting from the group consisting of substantially isotropically, two-dimensionally, conformally, over a large surface area, and over an entire surface area.

36. The method according to claim 30, which comprises forming at least one of the first electrode region, the dielectric region, and the second electrode region with a process selected from the group consisting of deposition, a CVD process, an ALD process, an electrochemical conversion, and a deposition process.

37. The method according to claim 32, which comprises forming one of the first electrode region and the second electrode region at least in part from a material selected from the group consisting of Al, W, WN, Ta, TaN, Ti, TiN, Hf, HfN, Zr, ZrN, Mo, MoN, Y, YN, La, LaN, Ce, CeN, a combination thereof, and a compound thereof.

38. The method according to claim 32, which comprises forming the dielectric region at least in part from a material selected from the group consisting of Al₂O₃, Tiₒ2, Ta₂O₃, HfO₂, ZrO₂, WO₃, MoO₂, Y₂O₃, La₂O₃, CeO₂, MgO, a combination thereof, and a compound thereof.

39. The method according to claim 32, which comprises forming the capacitor device as a trench-structure capacitor device.

40. The method according to claim 39, wherein
forming a trench structure having a trench, including walls, edges, and a base, in the structure selected from the group consisting of a semiconductor substrate, a passivation region, an insulation region, and a surface region thereof; and
forming an arrangement having the first electrode region, if appropriate a second electrode region, and the dielectric region provided between them, in this order and in continuous form, at least in the region of the trench, and
covering and lining wall regions or edge regions and base regions of the respective trench with a part of the first electrode region, if appropriate of the second electrode region, and the dielectric region.

41. A method of fabricating a capacitor device for a semiconductor circuit configuration, comprising:
providing a structure selected from the group consisting of a semiconductor substrate, a passivation region, an insulation region, and a surface region thereof;
forming in the structure a configuration of an electrode region and a dielectric region spatially adjacent thereto, in the recited order and in contiguous form; and thereby
forming the dielectric region at least in part from a material with an increased dielectric constant relative to SiO₂ and Si₃N₄;
first forming the electrode region; and
subsequently forming the dielectric region by electrochemical oxidation in a conformal manner.

42. The method according to claim 41, which comprises forming the electrode region at least in part with or from at least one material selected from the group consisting of metallic material and a metal nitride.

43. The method according to claim 42, wherein the electrode region is a first electrode region and the method further comprises forming at least one second electrode region spatially adjacent the dielectric region, such that the second electrode region consists at least in part of at least one metallic material or a metal nitride or includes such a material.

44. The method according to claim 43, which comprises forming at least one of the first electrode region, the dielectric region, and the second electrode region in layer form.

45. The method according to claim 43, which comprises forming at least one of the first electrode region, the dielectric region, and the second electrode region in multilayer form.

46. The method according to claim 43, which comprises forming at least one of the first electrode region, the dielectric region, and the second electrode region in each case by selecting from the group consisting of substantially isotropically, two-dimensionally, conformally, over a large surface area, and over an entire surface area.

47. The method according to claim 41, which comprises forming at least one of the first electrode region, the dielectric region, and the second electrode region with a process selected from the group consisting of deposition, a CVD process, an ALD process, an electrochemical conversion, and a deposition process.

48. The method according to claim 43, which comprises forming one of the first electrode region and the second electrode region at least in part from a material selected from the group consisting of Al, W, WN, Ta, TaN, Ti, TiN, Hf, HfN, Zr, ZrN, Mo, MoN, Y, YN, La, LaN, Ce, CeN, a combination thereof, and a compound thereof.

49. The method according to claim 41, which comprises forming the dielectric region at least in part from a material selected from the group consisting of Al₂O₃, Tiₒ2, Ta₂O₃, HfO₂, ZrO2, WO₃, MoO₂, Y₂O₃, La₂O₃, CeO₂, MgO, a combination thereof, and a compound thereof.

50. The method according to claim 41, which comprises forming the capacitor device as a trench-structure capacitor device.

51. The method according to claim 50, wherein
forming a trench structure having a trench, including walls, edges, and a base, in the structure selected from the group consisting of a semiconductor substrate, a passivation region, an insulation region, and a surface region thereof; and
forming an arrangement having the first electrode region, if appropriate a second electrode region, and the dielectric region provided between them, in this order and in continuous form, at least in the region of the trench, and
covering and lining wall regions or edge regions and base regions of the respective trench with a part of the first electrode region, if appropriate of the second electrode region, and the dielectric region.
